(19) United States
(12) Patent Application Publication
(10) Pub. No.: US 2013/0094171 A1
(43) Pub. Date: Apr. 18, 2013

(54) EXPANSION CARD WITH CABLE MANAGEMENT APPARATUS

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/298,308

(22) Filed: Nov. 17, 2011

(30) Foreign Application Priority Data
Oct. 13, 2011 (CN) 201110309492.9

(51) Int. Cl. H05K 7/00

(52) U.S. Cl. 361/826

(57) ABSTRACT

An expansion card includes a card body and a cable management apparatus. The card body includes a number of connecters with a number of cables. The cable management apparatus includes a main body. A first side of the main body is fixed to the card body beside the connectors. A second side of the main body forms a flange. A number of first cable management portions are formed on the flange. A number of second cable management portions extend on the main body. The cables can extend through either the first cable management portions or the second cable management portions.

### BACKGROUND

1. Technical Field

The disclosure generally relates to expansion cards and, particularly, to an expansion card having a cable management apparatus.

Connectors for an expansion card of a computer or a server are connected to cables and then electrically connected to other components. However, the cables adjacent to the connectors usually need to be guided to different directions in order to be connected to said other components, which often creates messy cables.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an expansion card with cable management apparatus, in accordance with an embodiment.

FIG. 2 and FIG. 3 are assembled, isometric view of the expansion card of FIG. 1, but showing different states of use.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

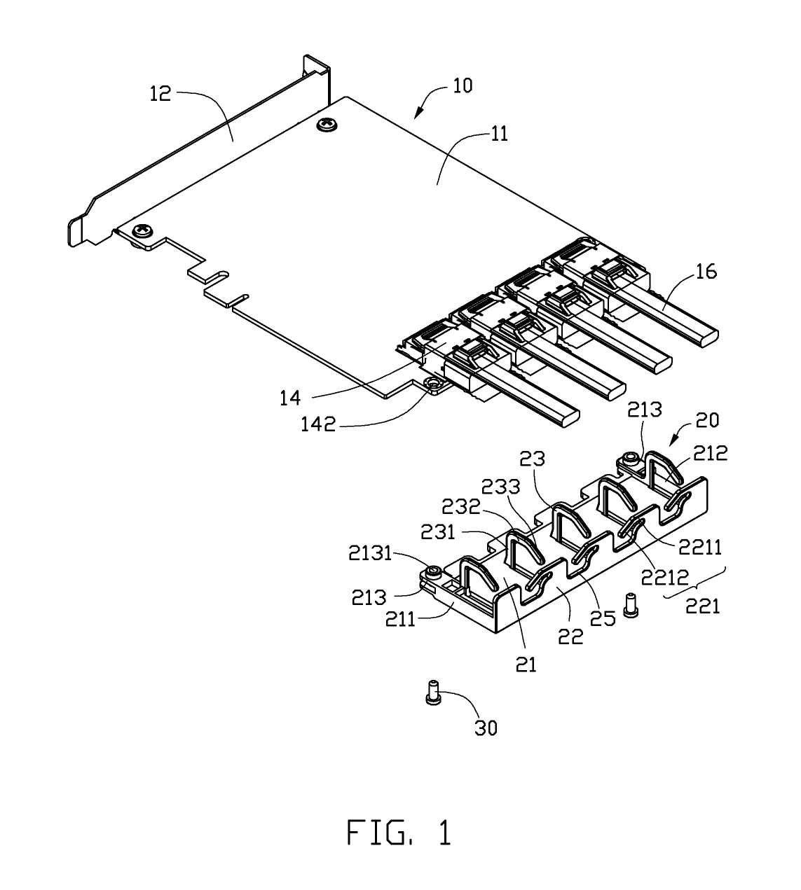

Referring to FIG. 1, an exemplary embodiment of an expansion card 10 includes a rectangular card body 11, a shielding piece 12 fixed to a first end of the card body 11, a plurality of connectors 14 mounted to a second end of the card body 11 opposite to the first end, and a cable management apparatus 20 for managing a plurality of cables 16 connected to the connectors 14.

The second end of the card body 11 defines two mounting holes 142 beside the connectors 14.

The cable management apparatus 20 includes a main body 21. A first end 211 and a second end 212 each form a U shaped clipping portion 213 at a first side of the main body 21. A through hole 2131 is defined in each clipping portion 213.

A flange 22 extends perpendicularly from a second side of the main body 21. The flange 22 defines a plurality of cutouts 25 in a top portion of the bent piece 22, to form a plurality of first cable management portions 221. Each first cable management portion 221 includes a cantilever 2211 extending toward the corresponding cutout 25 from the top of the flange 22 and parallel to the main body 21, and a blocking portion 2212 slantingly extending downwards from a distal end of the cantilever 2211.

A plurality of second cable management portions 23 extends upward from the main body 21, arranged along a lengthwise direction of the main body 21. Each second cable management portion 23 includes a supporting pole 231 extending upwards from the main body 21, a connecting pole 232 extending from a top of the supporting pole 231 toward a corresponding first cable management portion 221, and a blocking pole 233 extending slantingly downwards from a distal end of the connecting pole 232.

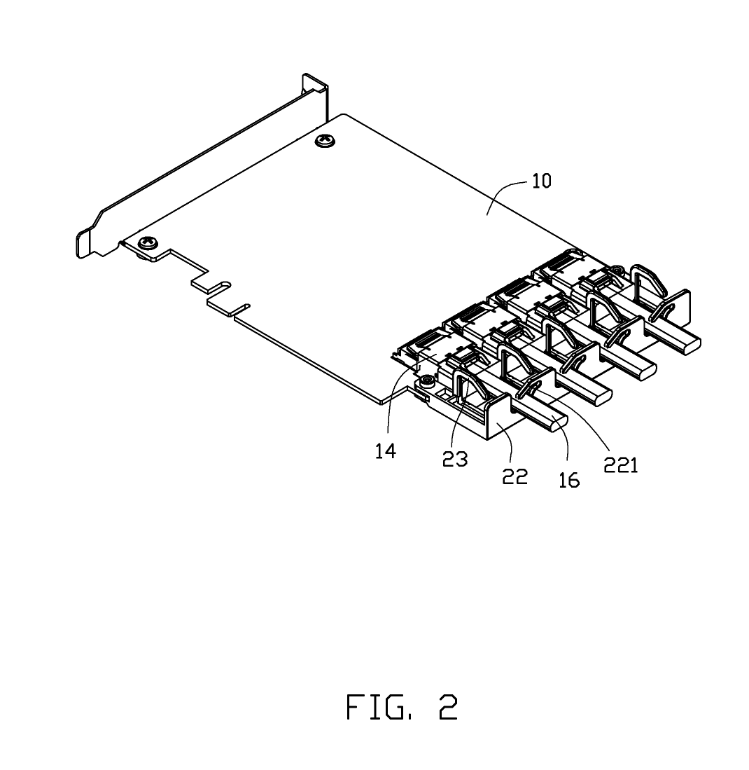

Referring to FIG. 2, in assembly, the clipping portions 213 sandwich the second end of the card body 11 beside the connectors 14. The through holes 2131 align with the corresponding mounting holes 142. Two fasteners 30 extend through the through holes 2131 and the mounting holes 142 to fix the cable management apparatus 20 to the card body 11. In this embodiment, the fasteners 30 are rivets.

In use, the cables 16 may extend through the corresponding cutouts 25 under the corresponding first cable management portions 221 along a lengthwise direction of the card body 11.

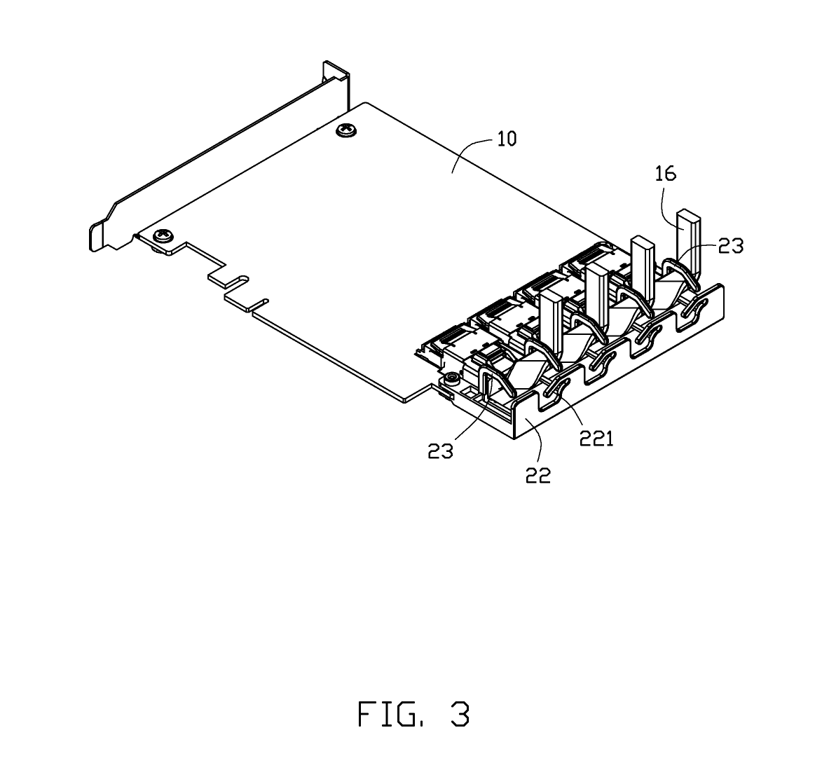

Referring to FIG. 3, the cables 16 also may extend under the corresponding second cable management portions 23 along a widthwise direction of the card body 11 perpendicular to the lengthwise direction.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A cable management apparatus comprising:
a main body;
a flange extending up from a side of the main body, the flange forming a plurality of first cable management portions; and
a plurality of second cable management portions extending up from the main body, wherein either the first cable management portions or the second cable management portions allow a plurality of cables to extend through.

2. The cable management apparatus of claim 1, wherein the first cable management portions are arranged along the side of the main body.

3. The cable management apparatus of claim 1, wherein the second cable management portions are arranged along a lengthwise direction of the main body substantially parallel to the side of the main body.

4. The cable management apparatus of claim 1, wherein the flange defines a plurality of cutouts through which the cables extend, each of the first cable management portions comprises a cantilever extending into a corresponding cutout from the flange and parallel to the main body, and a blocking portion extending down slantingly from a distal end of the cantilever.

5. The cable management apparatus of claim 4, wherein each of the second cable management portions comprises a supporting pole extending up from the main body, a connecting pole extending from a top of the supporting pole toward a corresponding one of the first cable management portions, and a blocking pole extending down slantingly from a distal end of the connecting pole.

6. An expansion card comprising:
a card body comprising a plurality of connectors arranged at an end of the card body, a plurality of cables connected to the connectors; and
a cable management apparatus comprising a main body, wherein a first side of the main body is fixed to the end of the card body, a flange extends up from a second side of the main body, the flange forms a plurality of first cable management portions, a plurality of second cable management portions extends up from the main body, the cables extend under either the corresponding first cable management portions or the corresponding second cable management portions.

7. The expansion card of claim 6, wherein the first cable management portions are arranged along the second side of the main body.

8. The expansion card of claim 6, wherein the second cable management portions are arranged along a lengthwise direction of the main body substantially parallel to the second side of the main body.

9. The expansion card of claim 6, wherein the flange defines a plurality of cutouts through which the cables extend, each of the first cable management portions comprises a cantilever extending from the flange into the corresponding cutout to block a corresponding cable.

10. The expansion card of claim 9, wherein the cantilever is parallel to the main body, a blocking portion extends down slantingly from a distal end of the cantilever.

11. The expansion card of claim 9, wherein each of the second cable management portions comprises a supporting pole extending up from the main body, a connecting pole extending from a top of the supporting pole toward a corresponding one of the first cable management portions, and a blocking pole extending down slantingly from a distal end of the connecting pole.

12. The expansion card of claim 9, wherein the card body defines two mounting holes beside the connectors, the main body forms a clipping portion on the first side, a through hole is defined in each of the clipping portions, two fasteners extend through the through holes and the mounting holes to fix the cable management apparatus to the card body.
